(19) United States
(12) Patent Application Publication
(10) Pub. No.: US 2006/0063382 A1
(43) Pub. Date: Mar. 23, 2006

(54) Method to fabricate copper-cobalt interconnects

(76) Inventors: Valery M. Dubin, Portland, OR (US); Chin-Chang Cheng, Portland, OR (US); Shaestagir Chowdhury, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/943,610

(22) Filed: Sep. 17, 2004

(51) Int. Cl. H01L 21/302

(52) U.S. Cl. 438/689

(57) ABSTRACT

A method to form copper-cobalt interconnects comprises rinsing a copper substrate with deionized water, heating a mild etchant solution and rinsing the copper substrate with the heated mild etchant solution, heating an electroless plating solution and rinsing the copper substrate with a portion of the heated electroless plating solution, heating a reducing agent solution and mixing another portion of the heated electroless plating solution with the heated reducing agent solution to form a self-catalytic bath, and applying the self-catalytic bath to the copper substrate. The electroless plating solution may contain cobalt ions. The method may further include rinsing the copper substrate with deionized water and a hydrofluoric acid solution after the application of the self-catalytic bath.

### TECHNICAL FIELD OF THE INVENTION

The invention generally relates to electroless plating, and more particularly to cobalt electroless plating in the fabrication of interconnect structures in integrated circuits.

### BACKGROUND

Electroless plating is a process for depositing a metal onto a surface by chemical reduction in the absence of an external electric current. Electroless plating is a selective deposition and occurs at locations on the surface that may have a nucleation potential for the plating solution. One process for electroless plating of a metal utilizes a metal ion, a pH-adjusting agent, a single complexing/buffering agent to maintain the metal in solution, at least one reducing agent, and optionally a wetting agent.

In the manufacture of integrated circuits on a semiconductor wafer, an electroless plating process can be used to deposit cobalt layers atop copper interconnect structures. The deposition of this cobalt “cap” on the copper metal improves the performance of the copper interconnects and increases the electromigration resistance of the interconnects to reduce leakage of electrons into the surrounding dielectric layers.

Current electroless plating processes for cobalt on copper suffer from quality issues. For instance, current processes tend to produce cobalt layers that are discontinuous and non-uniform due to poor nucleation at the copper surface. Current processes also require long nucleation times that unfortunately permit chemical reactions to occur that result in pitting and corrosion on the copper surface. In addition, electroless cobalt baths tend to be unstable and generate particles in the volume of the bath that are then deposited on the surface of the semiconductor wafer during the electroless plating process. These particles contaminate the wafer surface and often result in line-to-line leakage. Stable electroless cobalt baths can be made with hypophosphite and palladium activation, however, palladium tends to etch and/or contaminate the copper surface and increases the resistance of the copper interconnects. Palladium also increases the cost of the electroless cobalt process.

### BRIEF DESCRIPTION OF THE DRAWINGS

FIG. 1 illustrates an electroless plating system according to an implementation of the invention.

FIG. 2 is an electroless plating method according to an implementation of the invention.

FIG. 3 is a post-plating cleaning method according to an implementation of the invention.

FIG. 4 is a method for forming a cobalt-on-copper interconnect structure according to an implementation of the invention.

FIG. 5A illustrates a cobalt-on-copper interconnect formed using prior art methods.

FIG. 5B illustrates a cobalt-on-copper interconnect formed using a method of the invention.

### DETAILED DESCRIPTION

Described herein are methods of forming metal-on-metal interconnect structures, such as cobalt-on-copper, that are substantially uniform and do not cause damage to either metal. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

The invention is a method to form a uniform and continuous metal layer atop a substrate. In one implementation, the invention is an electroless cobalt deposition method with substantially uniform nucleation and corrosion-free copper, as well as self-aligned cobalt-copper interconnect structures. For example, in one implementation the invention can be used to form a uniform and continuous cobalt layer atop a copper interconnect structure. The cobalt-copper interconnect structure generally contains recessed copper lines (<10 nm) and in-laid cobalt caps aligned to the copper lines, with no plating on the barrier layers. As used herein, the term “substrate” refers to any surface that can be plated upon using an electroless process, such as a metal surface, which includes but is not limited to a copper interconnect structure.

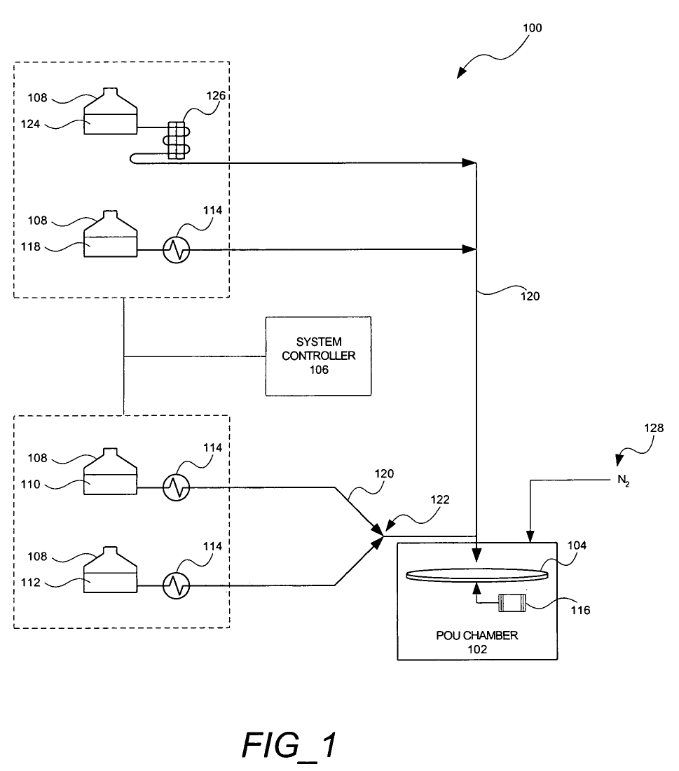

FIG. 1 is a simplified diagram illustrating an electroless plating system 100 (referred to herein as the EL system 100) according to one implementation of the invention. As illustrated, the EL system 100 includes a point of use (POU) process chamber 102 (referred to hereinafter as the POU chamber 102) that holds at least one semiconductor wafer 104 during an electroless plating process. The POU chamber 102 is where a self-catalytic bath is applied to the semiconductor wafer 104 to carry out an electroless plating process. The surface of the semiconductor wafer 104 contains one or more substrates, such as copper interconnect structures, upon which a metal is deposited during the electroless plating process. In various implementations, the POU chamber 102 may be a spray type, a microcell type, a spin on type, or other electroless plating chambers of the like.

In implementations of the invention, the POU chamber 102 may have a non-oxidizing atmosphere provided by an inert gas such as helium, argon, or nitrogen gas. Alternate inert gases may be used as well. In FIG. 1, as shown by reference numeral 128, the POU chamber 102 uses nitrogen gas to provide an inert atmosphere for the electroless plating process. Furthermore, in an implementation of the invention, the POU chamber 102 may include a heating element 116 capable of heating the semiconductor wafer 104 to a process temperature that facilitates the electroless plating process. For instance, the heating element 116 may heat the semiconductor wafer 104 to a temperature in the range of approximately 30° C. to 90° C.

The EL system 100 also includes a number of chemical tanks 108. In one implementation, the chemical tanks 108 store an electroless plating solution 110 and a reducing agent solution 112. When combined, the electroless plating solution 110 and the reducing agent solution 112 form a self-catalytic bath that is capable of depositing a metal on a substrate during an electroless plating process. Unfortunately, the combination of the electroless plating solution 110 and the reducing agent solution 112 tends to be unstable and generates particles in the volume of the bath that may contaminate the semiconductor wafer 104. To minimize particle generation, the EL system 100 stores the electroless plating solution 110 and the reducing agent solution 112 in separate chemical tanks 108 and keeps them separate until just prior to applying them to the semiconductor wafer 104 in the POU chamber 102.

In another implementation, the EL system 100 may store each of the constituents of the electroless plating solution 110 in separate chemical tanks 108. For instance, if the electroless plating solution 110 includes metal solutions, complexing and buffering agents, pH adjusting agents, and surfactants, the EL system 100 may include a first chemical tank 108 for the metal solutions, a second chemical tank 108 for the complexing and buffering agents, a third chemical tank 108 for the pH adjusting agents, and a fourth chemical tank 108 for the surfactants. The chemical tanks 108 may be tanks of any type suitable for the particular chemicals they are holding.

In yet another implementation, one or more chemical canisters (not shown) may be coupled to one or more of the chemical tanks 108 to store components of the electroless plating solution 100 and the reducing agent solution 112 in bulk form. The chemical canisters may feed the required components of the electroless plating solution 100 and/or the reducing agent solution 112 into each of their respective chemical tanks 108 where the components are combined.

In accordance with the invention, at least one chemical tank 108 may store a mild etchant solution 118. This mild etchant 118 may be an acidic solution with a volume concentration of less than ten percent. In one implementation the mild etchant 118 may be an organic acid such as citric acid, oxalic acid, acetic acid, or lactic acid. The pH of the mild etchant may range from pH 1 to pH 6. In other implementations, alternate chemicals suitable for etching a metal such as copper can be used as the mild etchant 118. In an implementation, one or more chemical canisters (not shown) may be coupled to the chemical tank 108 to store components of the mild etchant solution 118 in bulk form.

One or more in-line heaters 114 may be coupled to the chemical tanks 108, such as the chemical tanks 108 that store the electroless plating solution 110, the reducing agent solution 112, and the mild etchant solution 118. The in-line heaters 114 may heat these chemicals to an application temperature prior to being applied to the semiconductor wafer. The exact temperature that the chemicals are heated to is application dependent. In some implementations, the electroless plating solution 110 and the reducing agent solution 112 can be heated to different temperatures. In some implementations, the in-line heaters 114 may heat the electroless plating solution 110 and the reducing agent solution 112 to a temperature in the range of approximately 30° C. to 90° C. And in some implementations, the in-line 114 heaters may heat the mild etchant 118 to a temperature in the range of approximately 30° C to 90° C.

Also in accordance with the invention, another chemical tank 108 may be used to store deionized water 124 that may be used as a rinse agent before, during, and after the electroless plating process. If necessary, an in-line cooling device 126 may be coupled to the chemical tank 108 that stores the deionized water 124 to cool the deionized water 124 before it is applied to the semiconductor wafer 102 as a rinse agent. Generally, if the deionized water 124 is stored at ambient temperature, the in-line cooling device 126 is not needed. If the temperature of the deionized water 124 is higher than 30° C., then the in-line cooling device 126 may be used to reduce the temperature of the water 124. In an implementation, the cooling device 126 may be an air cooling evaporator or a heat exchanger. In an implementation, if the temperature of the deionized water 124 is higher than 30° C., the cooling device 126 may adjust the temperature of the deionized water 124 to be within a range of approximately 10° C. to 30° C.

In an implementation, the chemical tanks 108 are separately routed to the POU chamber 102 by a piping system 120, as shown in FIG. 1, which generally includes the in-line heaters 114 and the in-line cooling device 126. The EL system 100 may drive one or more of the chemicals from the chemical tanks 108 to the POU chamber 102 through the piping system 120. In one implementation, one or more pumps (not shown) may be used to drive the flow of chemicals through the piping system 120. In another implementation, pressurized tanks are used which do not require pumps. In one implementation, the EL system 100 may drive the electroless plating solution 110 and the reducing agent solution 112 simultaneously to combine them at a point 122 of the piping system 120 where their routings intersect. When the electroless plating solution 110 and the reducing agent solution 112 are combined at point 122, they form the self-catalytic bath used in the electroless plating process. Point 122 of the piping system 120 is substantially just prior to the point of application to the semiconductor wafer 104 within the POU chamber 102. In other implementations, the electroless plating solution 110 and the reducing agent solution 112 can be combined with other chemicals, including but not limited to surfactants, at point 122 just prior to being applied to the semiconductor wafer 104. In implementations where all of the constituents of the electroless plating solution 110 and/or the reducing agent solution 112 are stored in separate chemical tanks 108, the mixing of all of the constituents may occur at point 122 of the piping system 120. In an implementation, any suitable mixing device may be included at point 122 to achieve a substantially homogeneous solution.

The EL system 100 further includes a system controller 106 coupled to the chemical tanks 108, the in-line heaters 114, and the in-line cooling device 126. The system controller 106 controls the operation of the EL system 100. In various implementations, the system controller 106 may be a special purpose or general purpose computing device, provided it has the appropriate input and output interfaces for interfacing with the various chemical tanks 108, in-line heaters 114, and the in-line cooling device 126. In some implementations, these interfaces may be serial or parallel interfaces of a variety of types.

In accordance with an implementation of the invention, the electroless plating solution 110 may include one or more metal solutions, one or more complexing and buffering agents, one or more pH adjusting agents, and one or more additives such as surfactants. The exact composition, including the amount of contribution of each constituent chemical, is application dependent.

In one implementation, the metal solution used in the electroless plating solution 110 is a solution of cobalt ions. The cobalt ions may then be deposited on the copper interconnect structures of the semiconductor wafer 104 during the electroless plating process of the invention. In other implementations, metals other than cobalt may be used. For instance, in various implementations of the invention, the metal chosen to form a layer atop the interconnect structures can be one or more of the following metals: silver, gold, nickel, copper, iron, palladium, platinum, rhodium, iridium, or combinations thereof. While the amount of contribution of each constituent metal is application dependent, in one implementation the chosen metal or metals may be supplied in a concentration range from about 2 grams/liter (g/L) to about 50 g/L. In another implementation, the chosen metal or metals may be supplied in a concentration range from about 5 g/L to about 35 g/L.

In some implementations of the invention, at least one secondary metal may be added to the electroless plating solution 110. The at least one secondary metal may be selected from the group of chromium, molybdemum, tungsten, manganese, technetium, rhenium, ruthenium, osmium, and combinations thereof. While the amount of contribution of each secondary metal is application dependent, in one implementation the secondary metal or metals may be supplied in a concentration range from about 1 g/L to about 40 g/L. In another implementation, the secondary metal or metals may be supplied in a concentration range from about 2 g/L to about 35 g/L.

In accordance with an implementation of the invention, a single compound may act as a complexing and buffering agent for the electroless plating solution 110. In one implementation, an organic sulphate salt compound may be used in the electroless plating solution 110. Another implementation may include ammonium sulphate (NH₄)₂SO₄ and the like. Other single-compound complexing and buffering agents may be selected that have an effective gram equivalent amount to the (NH₄)₂SO₄. While the amount of contribution of the complexing and buffering agent is application dependent, in one implementation the complexing and buffering agent is supplied in a concentration range from about 50 g/L to about 1,000 g/L. In another implementation, the complexing and buffering agent is supplied in a concentration range from about 80 g/L to about 600 g/L.

In another implementation, separate complexing agents and buffering agents may be used. For instance, in one implementation the complexing agent may be citric acid, malonic acid, glycine, or ethylenediamine tetraacetic acid (EDTA), while the buffering agent may be NH₄Cl or a boric acid.

In accordance with implementations of the invention, one or more pH-adjusting agents may be included in the electroless plating solution 110. The pH-adjusting agents may include organic and inorganic bases. In one implementation, organic base agents that may be used include one or more organic amines such as pyridine, pyrrolidine, methylamine, dimethylamine, trimethylamine, ethylamine, diethylamine, triethylamine, and the like. Other implementations of the electroless plating solution 110 may include one or more bases such as tetramethylammonium hydroxide (TMAH), tetraethyl ammonium hydroxide (TEAH), tetrapropyl ammonium hydroxide (TPAH), tetrabutyl ammonium hydroxide (TBAH), potassium hydroxide (KOH), ammonium hydroxide (NH₄OH), aniline, toluidine, and the like. In an implementation, the pH adjusting agents are used to adjust the pH level of the self-catalytic bath, depending on the specific complexing agents, buffering agents, and reducing agents that are chosen. For instance, if citric acid is used, then the pH level may be adjusted to fall within a range of pH 8 to pH 10; if EDTA is used, the pH level may be adjusted to be within a range of pH 12 to pH 13.5; and if succinic acid is used, the pH level can be adjusted to be between pH 6 and pH 8.

While the amount of contribution of the organic base compounds is application dependent, in one implementation the particular base agent that is chosen may be TMAH and the amount of its contribution may range from approximately 30 mL to approximately 150 mL, which is added to approximately a 100 mL volume of the other constituents of the electroless plating solution 110. Further implementations include the gram equivalent amounts of the organic base compounds set forth herein.

In implementations of the invention, inorganic base compounds may be used that are salts of strong bases and weak acids. In one implementation, the electroless plating solution 110 may include one or more alkali metal acetates, alkaline earth metal acetates, alkali metal propionates, alkaline earth metal propionates, alkali metal carbonates, alkaline earth metal carbonates, alkali metal hydroxides, and alkaline earth metal hydroxides. In one implementation, combinations of at least two of the acetates, propionates, carbonates, and hydroxides may be used.

While the amount of contribution of the inorganic base compounds is application dependent, in some implementations the inorganic base compounds may be provided in a concentration such as a 25% NH₄OH in deionized water solution, to make a volume of about 10 mL to about 50 mL. This volume of solution may be added to an about 100 mL volume of the electroless plating solution 110. Further implementations may include the gram equivalent amounts of the inorganic base compounds set forth herein.

In implementations of the invention, further compounds or additives may be included in the electroless plating solution 110, including but not limited to surface active agents. One commercial surfactant that may be used is RHODAFAC RE 610, made by Aventis (formerly Rhone-Poulenc Hoechst). Another commercial surfactant that may be used is Triton x-100TTM made by Sigma-Aldrich. Other surfactants include, but are not limited to, cystine, polyethylene glycols, polypropylene glycol (PPG)/polyethylene glycol (PEG) (in a molecular range of approximately 200 to 10,000) in a concentration range of about 0.01 to 5 g/L, and the like.

In implementations of the invention, one or more reducing agents are included in the reducing agent solution 112 to assist in assuring metal deposition as the chemical environment of the substrate onto which the metal deposits continues to change. Although initial deposition of a primary metal onto a substrate may be autocatalytic, the changing chemical environment may interrupt the autocatalytic environment. For instance, in an implementation where deposition is upon a copper substrate, initial deposition will be achieved in the presence of the copper. The copper substrate affects the initial, presumably oxidation-reduction (redox) deposition chemistry. As the copper substrate is covered by a deposition metal such as cobalt, however, the redox chemical environment changes from a cobalt-onto-copper plating to a cobalt-onto-cobalt plating. Accordingly, at least one reducing agent is provided to assure continued cobalt plating despite the changed chemical environment.

In one implementation, the reducing agent solution 112 may include at least one reducing agent that contains boron. In implementations of the invention, the at least one reducing agent may be ammonium, alkali metal, alkaline earth metal borohydrides, and the like, and combinations thereof. In some implementations, the at least one reducing agent may be inorganic and include one or more of sodium borohydride, lithium borohydride, zinc borohydride, and the like. In other implementations, the reducing agent may be organic and include dimethylamineborane (DMAB). In further implementations, one or more other amineboranes are used such as diethylamineborane, morpholine borane, and the like. In still other implementations, the reducing agent may include hypophosphite, formaldehyde, hydrazine, or glyoxylic acid. The exact composition, including the amount of contribution of each reducing agent, is application dependent. In one implementation, at least one primary reducing agent may be supplied in a concentration range from about 1 g/L to about 30 g/L. In another implementation, at least one primary reducing agent may be supplied in a concentration range from about 2 g/L to about 20 g/L.

In further implementations of the invention, a secondary reducing agent may be included in the reducing agent solution 112 to assist the changing chemical environment during deposition of the metals. In one implementation a phosphorus-containing compound is selected as the secondary reducing agent. Phosphorus-containing compounds may include hypophosphites. In one implementation, the hypophosphite may be selected from non-alkaline metal hypophosphites such as ammonium hypophosphite and the like. In another implementation, the hypophosphite may be selected from alkaline metal hypophosphites such as sodium hypolphosphite and the like. In implementations of the invention, the secondary reducing agent may include one or more inorganic phosphorus-containing compounds such as hypophosphites of lithium, sodium, potassium, magnesium, calcium, strontium, and nickel. One implementation may include an inorganic phosphorus-containing compound such as hypophosphorous acid and the like.

The secondary reducing agents, in other implementations, may be selected from sulfites, bisulfites, hydrosulfites, metabisulfites, dithionates, tetrathionates, thiosulfates, thioureas, hydrazines, hydroxylamines, aldehydes, glyoxylic acid, reducing sugars, diisobutylaluminum hydride, sodium bis(2-methoxyethoxy)aluminum hydride, and other compounds that are similar to the compounds listed herein. The exact composition, including the amount of contribution of each secondary reducing agent, is application dependent. In one implementation, at least one secondary reducing agent may be supplied in a concentration range from about 0 g/L to about 5 g/L. In another implementation, at least one secondary reducing agent may be supplied in a concentration range from about 1 g/L to about 2 g/L.

In one implementation of the invention, the primary reducing agent is DMAB in a concentration range from about 2 g/L to about 30 g/L, and the secondary reducing agent is ammonium hypophosphite in a concentration range from about 0 g/L to about 10 g/L, and preferably 1 g/L to 3 g/L. Other implementations include primary and secondary reducing agents that are substituted for one or both of DMAB and ammonium hypophosphite as long as they approximate the gram equivalent amounts of the primary and secondary reducing agents. The gram equivalent amounts may be adjusted by various means, such as according to the comparative dissociation constants of the reducing agents.

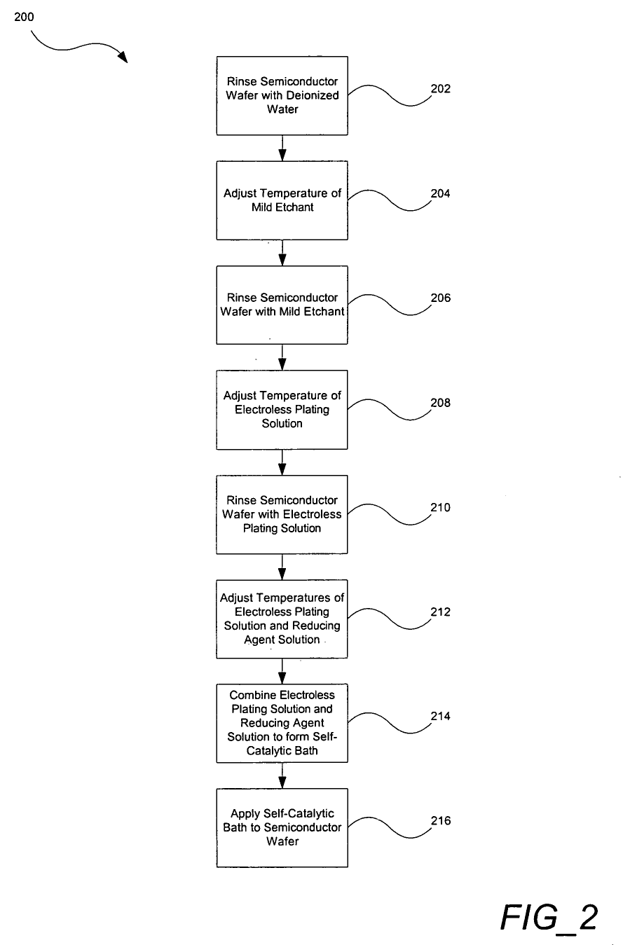

FIG. 2 describes an electroless plating process 200 in accordance with an implementation of the invention. The electroless plating process 200 begins with the EL system rinsing the semiconductor wafer with deionized water within the POU chamber (202). The purpose of this first rinse is to generally clean the surface of the semiconductor wafer and remove any foreign particles or debris. In one implementation, the EL system activates a pump to drive the deionized water through the piping system towards the POU chamber. If the temperature of the deionized water is greater than or equal to 30° C., the EL system can adjust the temperature of the deionized water using the in-line cooling device. In an implementation, the temperature of the deionized water can be adjusted so that it is in the range of 10° C. to 30° C. Generally, if the deionized water is stored at ambient temperature, a temperature reduction is not necessary unless the ambient temperature is greater than 30° C.

After the semiconductor wafer is rinsed with the deionized water, the EL system causes the mild etchant to flow and heats the mild etchant using an in-line heater (204). In one implementation, the EL system activates a pump that drives the mild etchant through the piping system and the in-line heater. In one implementation, the in-line heater adjusts the temperature of the mild etchant to be approximately in the range of 30° C. to 90° C. The heating of the mild etchant tends to enhance its etching ability.

Next, the EL system applies the heated mild etchant to the semiconductor wafer within the POU chamber (206). In an implementation, the EL system may spray the mild etchant onto the semiconductor wafer. As noted above, the EL system uses a pump to drive the mild etchant flow. In one implementation, the application of mild etchant to the semiconductor wafer lasts for approximately one or ten minutes. The application of the heated mild etchant serves a few purposes. In an implementation, one purpose of the mild etchant application is to etch any oxide that has formed on the metal surfaces being plated. For instance, if the surfaces to be plated are copper interconnect structures, the mild etchant rinse will tend to etch the copper to remove at least a portion of any copper oxide that has formed. Some copper oxide may form during the previous deionized water rinse (202), so the mild etchant rinse can remove at least a portion of that oxidation.

In an implementation, another purpose of the mild etchant rinse is to remove any organics that were left behind by earlier chemical mechanical polishing (CMP) processes, for example, such processes used to create copper interconnect structures. Some of the organics left behind by earlier CMP processes include, but are not limited to, benzotriazole (BTA). And in an implementation, since the mild etchant is heated to a temperature approximately in the range of 30° C. to 90° C. (204), another purpose of the heated mild etchant rinse is to preheat the semiconductor wafer prior to the electroless plating process. A preheated semiconductor wafer tends to decrease the nucleation time needed during a subsequent electroless plating process, thereby reducing the corrosion or pitting of metal that can occur. For instance, in one implementation, the preheating of the semiconductor wafer can reduce the nucleation time needed for cobalt to plate on copper during an electroless process from approximately two minutes to approximately a few seconds.

In an implementation, the heating element can also be used to preheat the semiconductor wafer within the POU chamber prior to the electroless plating process. In one implementation, the heating element is used in combination with the mild etchant to heat the semiconductor wafer to an application temperature. In other implementations, the heating element is used to preheat the semiconductor wafer and maintain the semiconductor wafer at the application temperature during the electroless plating process.

Next, the EL system adjusts the temperature of the electroless plating solution using an in-line heater (208). In one implementation, the EL system activates a pump that drives the electroless plating solution through the piping system and the in-line heater. In one implementation, the in-line heater adjusts the temperature of the electroless plating solution to be approximately in the range of 30° C. to 90° C.

The EL system then rinses the semiconductor wafer with the heated electroless plating solution (210). In an implementation, the EL system may spray the electroless plating solution onto the semiconductor wafer, for instance, using a spray tool. The application of the electroless plating solution tends to last approximately five to thirty seconds and is used to rinse the mild etchant off the surface of the semiconductor wafer. The electroless plating solution also tends to increase the pH level of the liquid film on metal surfaces. Using the electroless plating solution as a rinse agent here is advantageous over other rinse agents such as water because oxidation of the metal surface does not occur.

In an implementation, the EL system then preheats both the electroless plating solution and the reducing agent solution to an application temperature (212). To do this, the EL system uses one or more pumps to drive the electroless plating solution and the reducing agent solution through the piping system. As the solutions flow through the piping system, the in-line heaters adjust the temperature of the solutions to be within a range of approximately 30° C. to 80° C. In an implementation, the electroless plating process requires that the electroless plating solution and the reducing agent solution be within this temperature range for the electroless plating to occur.

After being heated, the EL system combines the electroless plating solution and the reducing agent solution to form a self-catalytic bath (214). In one implementation, the EL system drives both solutions to a point in the piping system (i.e., point 122 of FIG. 1) where the two streams are combined into one stream. In other implementations, alternative methods of combining the electroless plating solution and the reducing agent solution to form the self-catalytic bath may be used, for instance, mixing the solutions in a chemical tank.

Once the self-catalytic bath is formed, the EL system applies the bath to the seimiconductor wafer within the POU chamber (216). In one implementation, the EL system uses a spray tool to spray the self-catalytic bath onto the surface of the semiconductor wafer. In an implementation, the temperature of the self-catalytic bath tends to be within the range of approximately 30° C. to 80° C. due to the in-line heaters, and the pH level of the self-catalytic bath tends to be within a range of approximately pH 8 to pH 10 due to the pH adjusting agents. The self-catalytic bath comes into contact with the semiconductor wafer and the electroless plating process occurs. The metal ions from the self-catalytic bath deposit onto metal substrates on the semiconductor wafer, and as mentioned above, the nucleation time needed for the deposition to occur is substantially reduced. In one implementation, the self-catalytic bath contains cobalt ions that deposit onto copper interconnect structures found on the semiconductor wafer. The cobalt ions form cobalt layers that are aligned to the copper interconnects with uniform nucleation and little or no plating on the barrier layers. Due to the reduced nucleation time, the cobalt layers are formed with reduced copper corrosion and pitting compared to previously known methods. In further implementations, metals other than cobalt can be used for plating on copper interconnects, including but not limited to nickel, tin, molybdenum, rhenium, tungsten, silver, gold, ruthenium, osmium, and iron, as well as alloys of these metals.

In an implementation of the invention, the electroless plating process 200 occurs under an inert and non-oxidizing atmosphere provided by the POU chamber. As detailed above, the inert atmosphere can be supplied using nitrogen gas. In an implementation, the above described steps of the electroless plating process 200 may be carried out in order with little or no delay between consecutive steps. In further implementations, two or more semiconductor wafers can be treated simultaneously within the POU chamber, with the wafers oriented face up or face down.

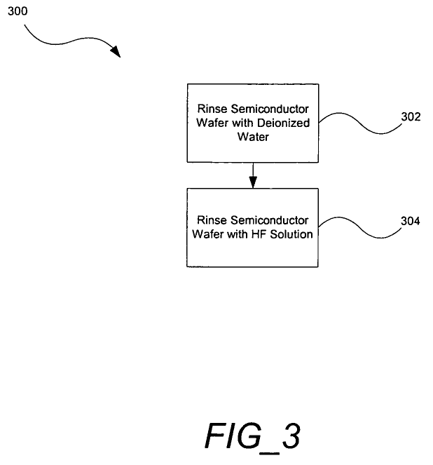

FIG. 3 illustrates an implementation for a post-plating cleaning process 300. In an implementation of the invention, after the electroless plating process 200 is complete, the EL system may rinse the semiconductor wafer with deionized water (302). In one implementation, the EL system activates a pump to drive the deionized water through the piping system towards the POU chamber. If the temperature of the deionized water is greater than or equal to 30° C., the EL system may adjust the temperature of the deionized water using the in-line cooling device so that it is in the range of 10° C. to 30° C. As explained above, if the deionized water is stored at ambient temperature, a temperature reduction is generally not necessary unless the ambient temperature is greater than 30° C.

After the deionized water rinse, the EL system rinses the semiconductor wafer using a diluted hydrofluoric acid solution (304). In one implementation, the diluted hydrofluoric acid solution has a concentration of less than 50:1 (i.e., there is less than one part hydrofluoric acid per 50 parts deionized water by weight). The application of the diluted hydrofluoric acid solution tends to remove possible contaminants from the surface of any dielectric material.

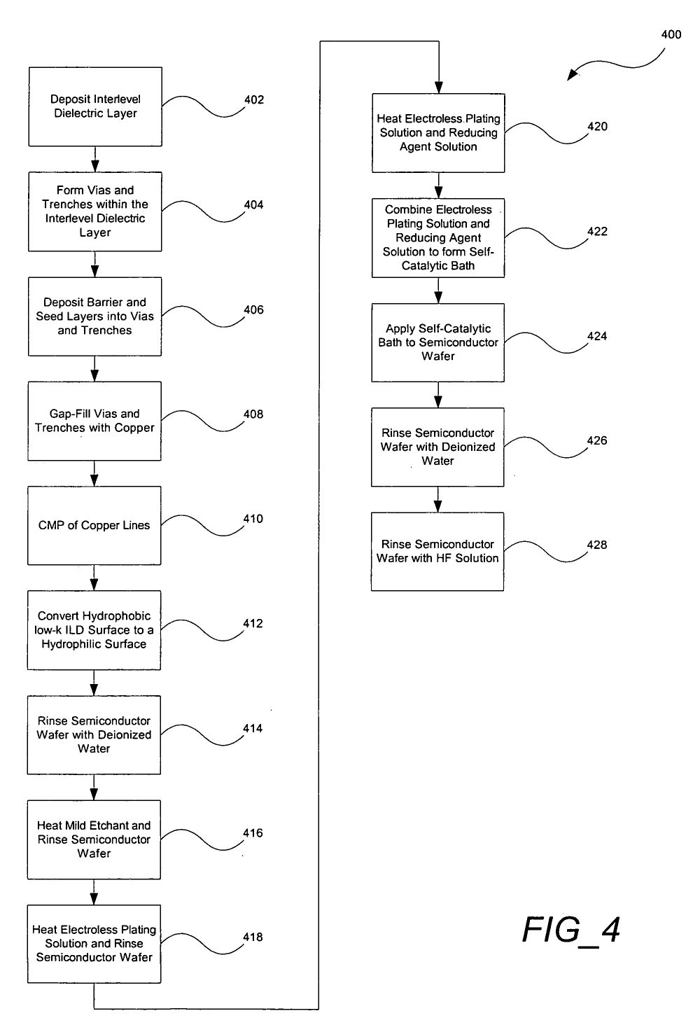

FIG. 4 illustrates an overall process 400 for creating copper-cobalt interconnect structures on a semiconductor wafer. The process begins with a deposition process to deposit an interlevel dielectric layer (ILD), such as silicon dioxide or carbon-doped oxide, on a semiconductor wafer (402). Optionally, in implementations of the invention, an etch stop layer such as silicon nitride (SiN), silicon nitro carbide (SiNC), or silicon carbide (SiC) can also be deposited. In further implementation, other etch stop layer materials can be used.

The process 400 continues by forming vias and trenches in the ILD (404). In an implementation, the vias and trenches may be formed using known photolithography techniques that generally involve processes such as depositing a photoresist layer, patterning the photoresist layer, developing the photoresist layer, etching the dielectric layer, and removing the remaining photoresist.

After the vias and trenches are formed, another deposition process occurs to deposit a barrier layer and a seed layer into the vias and trenches (406). Known deposition processes such as physical vapor deposition, chemical vapor deposition, atomic layer deposition, and electroless plating can be used to deposit the barrier and seed layers. In other implementations, alternative deposition processes can be used. The materials used in the barrier and seed layers include, but are not limited to, tantalum nitride (TaN), tantalum (Ta), and copper.

Next, a gap-fill deposition process occurs to provide gap-fill for the vias and trenches (408). The deposition process can again one or many known processes such as physical vapor deposition, chemical vapor deposition, atomic layer deposition, electroplating, and electroless plating. This deposition process fills the vias and trenches with a metal such as copper or aluminum. In an implementation, copper metal is chosen for the gap-fill process. Once the vias and trenches are filled with copper metal, a CMP process is necessary to polish the copper lines, including any copper interconnect structures (410).

The material used to form the ILD is generally a hydrophobic low-k material, so the process then converts the hydrophobic low-k ILD surface to a hydrophilic surface (412). In one implementation, a plasma treatment using hydrogen containing gas converts the ILD surface to hydrophilic. In another implementation, a wet treatment in glycols, alcohols or surfactants converts the ILD surface to hydrophilic.

Once the surface of the ILD is hydrophilic, the process 400 continues with the EL system rinsing the semiconductor wafer with deionized water (414). Next, the EL system heats the mild etchant to a temperature in the range of 30° C. to 90° C., and then rinses the semiconductor wafer with the heated mild etchant (416). As described above, the mild etchant rinse can last for approximately one to ten minutes.

After the mild etchant rinse, the EL system heats the electroless plating solution to a temperature in the range of 30° C. to 90° C. and rinses the semiconductor wafer with the heated electroless plating solution (418).

Next, the EL system preheats both the electroless plating solution and the reducing agent solution to an application temperature (420), the application temperature generally being in the range of approximately 30° C. to 80° C. After being heated, the EL system combines the electroless plating solution and the reducing agent solution to form the self-catalytic bath (422).

Once the self-catalytic bath is formed, the EL system applies the bath to the semiconductor wafer within the POU chamber (424). In one implementation, the EL system uses a spray tool to spray the self-catalytic bath onto the surface of the semiconductor wafer. The self-catalytic bath then comes into contact with the semiconductor wafer and the electroless plating process occurs.

After the electroless plating process is complete, the EL system carries out a post-plating rinse in deionized water (426) and a post-plating clean in diluted hydrofluoric acid solution (428). As described herein, one or more of the above processes may be carried out in an inert environment, which is generally provided by the POU chamber.

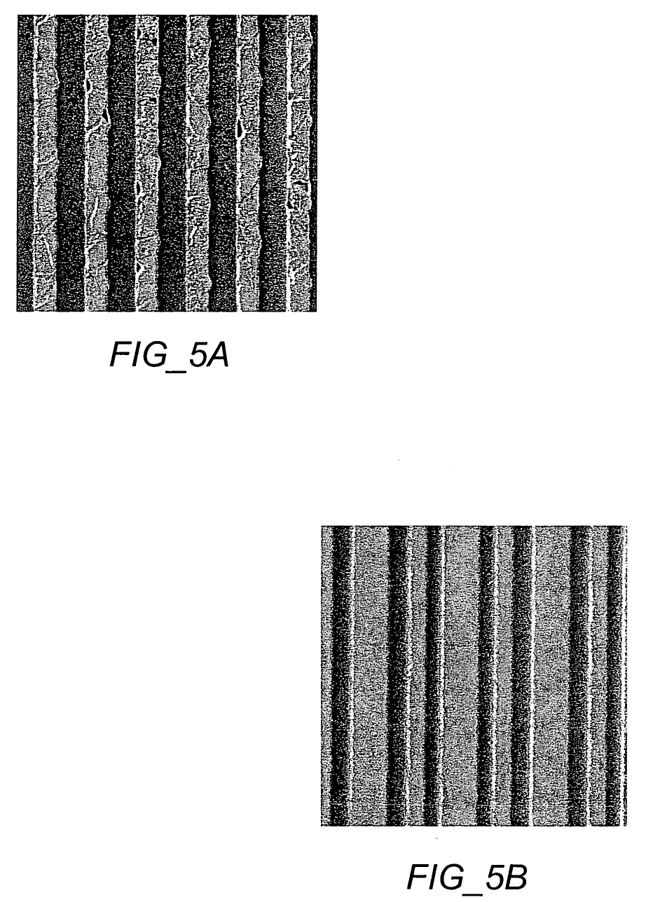

FIG. 5A illustrates a cobalt-on-copper deposition using previously known electroless plating processes. As shown in FIG. 5A, this previous method yields a cobalt layer that is non-uniform, has poor nucleation, and produces corrosion and pitting in the underlying copper layer.

FIG. 5B, on the other hand, illustrates a cobalt-on-copper deposition using the electroless plating process of the invention. As shown in FIG. 5B, the cobalt layer is uniform and aligned with the underlying copper. There is substantially no copper corrosion or pitting that occurs with the methods of the invention. The cobalt layers are self-aligned to the copper with substantially no side growth and decreasing line-to-line leakage. The uniform nucleation and contamination-free copper surface also increases the electromigration resistance of the interconnects.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
heating a mild etchant solution;
rinsing a metal substrate with the heated mild etchant solution;
heating an electroless plating solution;
rinsing the metal substrate with the heated electroless plating solution;
heating a reducing agent solution;
mixing the heated electroless plating solution with the heated reducing agent solution to form a self-catalytic bath; and
applying the self-catalytic bath to the metal substrate.

2. The method of claim 1, wherein the mixing of the heated electroless plating solution with the heated reducing agent solution occurs just prior to the applying of the self-catalytic bath to the metal substrate.

3. The method of claim 1, further comprising rinsing the metal substrate with deionized water prior to the rinsing of the metal substrate with the heated mild etchant solution.

4. The method of claim 1, wherein the mild etchant solution is heated to a temperature between approximately 30° C. and approximately 90° C.

5. The method of claim 1, wherein the mild etchant has a pH between approximately pH 1 and approximately pH 6.

6. The method of claim 1, wherein the mild etchant comprises an organic acid or an organic surfactant.

7. The method of claim 6, wherein
if the mild etchant comprises an organic acid, then the organic acid comprises at least one acid from the group consisting of citric acid, oxalic acid, acetic acid, and lactic acid,
else if the mild etchant comprises an organic surfactant, then the organic surfactant comprises at least one surfactant from the group consisting of polyethylene glycol and glycol.

8. The method of claim 1, wherein the electroless plating solution is heated to a temperature between approximately 30° C. and approximately 90° C.

9. The method of claim 1, wherein the electroless plating solution comprises a metal solution.

10. The method of claim 9, wherein the metal solution comprises at least one metal from the group consisting of cobalt, silver, gold, nickel, copper, iron, palladium, platinum, rhodium, iridium, chromium, molybdemum, tungsten, manganese, technetium, ruthenium, osmium, and rhenium.

11. The method of claim 9, wherein the electroless plating solution further comprises a complexing agent, a buffering agent, and a pH adjusting agent.

12. The method of claim 1, wherein the reducing agent solution is heated to a temperature between approximately 30° C. and approximately 90° C.

13. The method of claim 1, wherein the reducing agent solution comprises at least one chemical from the group consisting of borohydrides, dimethylamineborane, amineboranes, hypophosphites, formaldehyde, hydrazine, and glyoxylic acid.

14. The method of claim 1, further comprising:
rinsing the metal substrate with deionized water a second time after the applying of the self-catalytic bath; and
rinsing the metal substrate with a hydrofluoric acid solution after the second rinsing of the metal substrate with the deionized water.

15. The method of claim 1, wherein the applying of the self-catalytic bath to the metal substrate is performed using a spray-on process.

16. A method comprising:
routing a mild etchant solution for application to a wafer;
separately routing an electroless plating solution and a reducing agent solution for mixing and application to a wafer;
in-line heating the mild etchant solution, the electroless plating solution, and the reducing agent solution to an application temperature while they are being routed;
applying the heated mild etchant solution to the wafer;
in-line mixing the heated electroless plating solution and the heated reducing agent solution substantially just prior to application to the wafer; and
applying the mixture of the heated electroless plating solution and the heated reducing agent solution to the wafer.

17. The method of claim 16, further comprising:
routing a deionized water solution for application to a wafer; and
applying the deionized water solution to the wafer prior to the applying of the heated mild etchant solution to the wafer.

18. The method of claim 17, further comprising applying the deionized water solution to the wafer a second time after the applying of the mixture to the wafer.

19. The method of claim 16, wherein the mild etchant solution is heated to a temperature between approximately 30° C. and approximately 90° C.

20. The method of claim 16, wherein the electroless plating solution is heated to a temperature between approximately 30° C. and approximately 90° C.

21. The method of claim 16, wherein the reducing agent solution is heated to a temperature between approximately 30° C. and approximately 90° C.

22. The method of claim 16, wherein the mild etchant comprises an organic acid.

23. The method of claim 22, wherein the organic acid comprises at least one acid from the group consisting of citric acid, oxalic acid, acetic acid, and lactic acid.

24. The method of claim 18, further comprising:
routing a hydrofluoric acid solution for application to a wafer; and
applying the hydrofluoric acid solution to the wafer after the second applying of the deionized water solution to the wafer.

25. An electroless plating apparatus comprising:
a POU chamber to hold a semiconductor wafer during an electroless plating process;
a first chemical tank to store a mild etchant solution that is coupled to the POU chamber via a first routing;
a second chemical tank to store an electroless plating solution that is coupled to the POU chamber via a second routing;
a third chemical tank to store a reducing agent solution that is coupled to the POU chamber via a third routing; and
a fourth chemical tank to store a deionized water solution that is coupled to the POU chamber via a fourth routing;
wherein the second and third routings intersect just prior to the POU chamber to enable mixing of the electroless plating solution with the reducing agent solution.

26. The apparatus of claim 25, wherein the POU chamber has an inert atmosphere.

27. The apparatus of claim 25, further comprising:
a first in-line heater coupled to the first routing to heat the mild etchant solution;
a second in-line heater coupled to the second routing to heat the electroless plating solution; and
a third in-line heater coupled to the third routing to heat the reducing agent solution.

28. The apparatus of claim 25, further comprising an in-line cooling device coupled to the fourth routing to cool the deionized water solution.

29. The apparatus of claim 25, further comprising a system controller to operate the electroless plating apparatus.

30. The apparatus of claim 25, further comprising one or more pumps to move the solutions from the chemical tanks to the POU chamber.

31. The apparatus of claim 25, further comprising:
a fifth chemical tank to store a hydrofluoric acid solution that is coupled to the POU chamber via a fifth routing.

32. The apparatus of claim 25, further comprising one or more chemical canisters coupled to the first chemical tank to store components of the mild etchant solution in bulk form.

33. The apparatus of claim 25, further comprising one or more chemical canisters coupled to the second chemical tank to store components of the electroless plating solution in bulk form.

34. The apparatus of claim 25, further comprising one or more chemical canisters coupled to the third chemical tank to store components of the reducing agent solution in bulk form.

35. The apparatus of claim 31, further comprising one or more chemical canisters coupled to the fifth chemical tank to store components of the hydrofluoric acid solution in bulk form.
